(19) United States
(12) Patent Application Publication
(10) Pub. No.: US 2011/0260292 A1
(43) Pub. Date: Oct. 27, 2011

(54) Bipolar Junction Transistor Having a Carrier Trapping Layer

(76) Inventors: Chrong-Jung Lin, Hsin-Chu City (TW); Ya Chin King, Taipei (TW); Yi-Hung Tsai, Dashu Township (TW)

(21) Appl. No.: 12/859,025

(22) Filed: Aug. 18, 2010

(30) Foreign Application Priority Data
Apr. 22, 2010 (TW) 099112741

(51) Int. Cl. H01L 29/73

(52) U.S. Cl. 257/565; 257/E29.174

(57) ABSTRACT

A bipolar junction transistor having a carrier trapping layer, comprises a semi-conductor substrate including a well with a first type ions formed thereon; two impurity regions with a second type ions formed opposite with each other over the well; an insulation layer over the well, and edges extend over the second two impurity regions; and a carrier trapping layer formed over the insulation layer.

### FIELD OF THE INVENTION

The present invention is generally related to the field of semi-conductor device and, more particularly, to the field of bipolar junction transistors.

### DESCRIPTION OF THE PRIOR ART

Various kinds of transistors have been developed for the past years, the bipolar junction transistor (BJT) employs two adjacent P-N junctions, carriers are injected from one of the P-N junctions, and collected by another junction, thereby generating carrier current which is larger than the current of the control signal, it is so called the current gain. The device prior to the bipolar junction transistor is point contact transistor, invented in 1947 at the Bell Laboratory by John Bardeen, Walter Brattain, and William Shockley, and the structure was improved to an advanced structure having two P-N type junctions next year.

The basic structure of the bipolar junction transistor includes two reversed contact P-N junctions, with the combination of P-N-P and N-P-N. Three connected terminals are labeled with: emitter(E), base(B), and collector(C), the sources of the names relate to the operation functions of the transistor. If there is no bias, the so called depletion regions will be formed between the two P-N type junctions to isolate neutralized P-type region and N-type region. Not only the characteristics of the bipolar junction transistor, but also the operation regions of the device are in relation to the bias applied on the two P-N junctions. In the commonly used forward active region, the P-N type junction between the emitter region and the base region maintains forward bias, the P-N type junction between the base region and the collector region is in inverse bias, the bipolar junction transistor used for amplifier generally biases in this mode. Because the depletion region between the emitter region and the base region would be narrower when the forward bias is applied, the potential barrier corresponding to the carriers will be lower, the electronic holes of the emitter region penetrate into base region, electrons of base region infiltrate into the emitter region; while the depletion region of the base region to collector region will become wider, the potential barrier is higher enough to bar the carriers, thereby isolating these regions there-between.

The major different between the bipolar junction transistor and the device with two reversed contact P-N diodes is that the two junctions of bipolar junction transistor are closer than the other. Take a P-N-P type transistor having bias in forward active region as example, the electronic holes of emitter region injected into the N-type neutral region would be surrounded and shielded by majority carrier (electrons) at once, then diffuses toward the collector region, and recombined with the electrons. The uncombined electronic holes which reach the depletion region of the base-collector junction would be accelerated and swept into the collector region by electric field, the electronic holes are majority carrier in the collector, thereby connecting to external by drifting current through the ohmic contact and generating a collector current I_{C}. The collector current I_{C} is not proportional to the base-collector inverse bias. What is needed is that the current I_{Brec} supplied from the base for recombination, and the current I_{nBE} injected into the emitter from the base (this portion is not required for the transistor operation). The current I_{nBE} is recombination with the holes at the emitter, I_{nBE}=I_{Erec}.

For the design consideration of typical transistor, the doping concentration of the emitter is much higher than the one of the base, such that the majority carriers (holes; minor carrier of the base) of the emitter IpBE injected from the emitter to the base is much more than the carrier current InBE injected into emitter from the base, to enhance the efficiency of transistor. Simultaneously, if the narrower the width of neutral region in the base is, the shorter time the holes pass through the base, therefore, the lower possibility for recombination by majority, the higher of the effective hole current IpEC is. Consequently, the recombination current provided by the base is lower, the efficiency of the transistor is higher.

The magnitude of the hole current injected from the emitter to the base is controlled by the forward bias of the contact area between the emitter and the base, it is similar to the diode, small amount of the bias change may bring large amount of change to the current around the active potential. Precisely, the bipolar junction transistor controls the collector current IC by the change of VEB (or VBE), and the base current IB is far less than the collector current IC. The operation scheme of N-P-N type transistor is the same as P-N-P type transistor, only the bias and the current directions are opposite, namely, the roles of the electron and the hole are exchange. P-N-P type transistor uses VEB to control holes injected from emitter, through base, and into the collector. On the contrary, N-P-N type transistor employs VBE to control electrons injected from emitter, through the base, and into the collector. The efficiency of the transistor in forward active region can be defined by the ratio of the emitter current arrives at the collector. The bipolar junction transistor with highly efficiency may have less than 1% of emitter current recombined with base majority carrier in the base and the emitter, more than 99% of emitter current reaches the collector.

In order to improve the collector current, during the manufacture of the N-P-N type bipolar junction transistor, the electronic concentration of the emitter (that is, N type doping concentration) is higher than the one of the collector, so as to allow the electrons diffuse, easily; the P-N-P type transistor is the same, the hole concentration of the emitter (that is, P type doping concentration) is higher than the one of collector. It is because during the electrons travels through the base, the electrons are easy to be recombined with the holes, therefore, the base in the bipolar junction transistor would be made with thinner thickness. The thinner the base is, the shorter distance the electronic to travels, the carriers cross the base to reach the depletion region of base, easily. It can be seen that the carrier concentration of each regions and width of the base is essential to collector current.

One of the applications of the bipolar junction transistor in digital circuit is switch, namely, switching bipolar junction transistor between the forward active region (saturation region) and cutoff region by using the electronic signal. As a switch, the states of on and off refer to digital status of “zero” and “one” (or 1 and 0) in digital circuit. If bipolar junction transistor keeps biasing in forward active region continuously, minor electric signal change (may be voltage or current) between emitter and base may cause relatively large current change between the emitter and the collector. It can also be used as a signal amplifier.

The majority functions of trimming circuit are used for amplifier input stage, analog to digital converter, digital to analog converter, and so on. Normal trimming circuit are used for solving the problems of differential pairs mismatching, variable resistor are commonly employed for calibration prior to shipping out. However, the size of the resistor is generally larger than the one of the transistor in the integrated circuits, if the variable resistor is utilized as the trimming circuit, it occupies too much area, thereby increasing the manufacturing cost. For solving the problems described above, the present invention discloses a bipolar junction transistor having a carrier trapping layer.

### SUMMARY OF THE INVENTION

The object of the present invention is to provide a semiconductor device which can remove the variable resistor of trimming circuits.

Another object of the present invention is to input high-voltage pulse by using trimming circuits to bipolar junction transistor having a carrier trapping layer, for gradual increasing the current gain of single side transistor till the current gain match on both side, to reach the effect of self-adjustment.

The present invention discloses a bipolar junction transistor having a carrier trapping layer comprising: a semi-conductor substrate including a well with a first type ions formed thereon; two impurity regions with a second type ions formed opposite with each other over the well; an insulation layer over the well, and edges extend over the second two impurity regions; and a carrier trapping layer formed over the insulation layer.

The present invention also discloses a brand new electronic device, which means a bipolar junction transistor having a carrier trapping layer. It is similar to a parallel connecting structure of a non-volatile memory and a bipolar junction transistor, comprises: a bipolar junction transistor; and a non-volatile memory connected to the bipolar junction transistor in parallel; wherein the non-volatile memory includes a carrier trapping layer.

### BRIEF DESCRIPTION OF THE DRAWINGS

FIG. 1 illustrates the well-known structure of bipolar junction transistor.

FIG. 2 illustrates the structure of bipolar junction transistor having a carrier trapping layer.

FIG. 3 illustrates the detailed diagram of bipolar junction transistor having a carrier trapping layer when performing

FIG. 4 illustrates another detailed diagram of bipolar junction transistor having a carrier trapping layer when performing

FIG. 5 illustrates the Gummel plot of the actual efficacy of bipolar junction transistor having a carrier trapping layer of the present invention.

FIG. 6 illustrates the Gummel plot of the actual efficacy of bipolar junction transistor having a carrier trapping layer of the present invention.

FIG. 7 illustrates the Gummel plot of the actual efficacy of bipolar junction transistor having a carrier trapping layer of the present invention.

FIG. 8 illustrates the Gummel plot of the actual efficacy of bipolar junction transistor having a carrier trapping layer of the present invention.

FIG. 9 illustrates the Gummel plot of the actual efficacy of bipolar junction transistor having a carrier trapping layer of the present invention.

FIG. 10 illustrates the Gummel plot of the actual efficacy of bipolar junction transistor having a carrier trapping layer of the present invention.

FIG. 11 illustrates the output feature plot of the actual efficacy of bipolar junction transistor having a carrier trapping layer of the present invention.

FIG. 12 illustrates the output feature plot of the actual efficacy of bipolar junction transistor having a carrier trapping layer of the present invention.

FIG. 13 illustrates the equivalent circuit of the present invention.

### DESCRIPTION OF THE PREFERRED EMBODIMENT

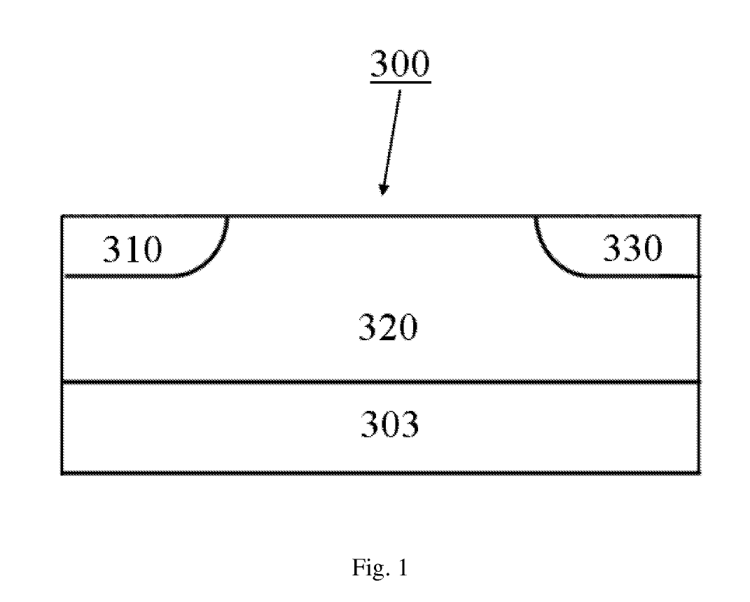

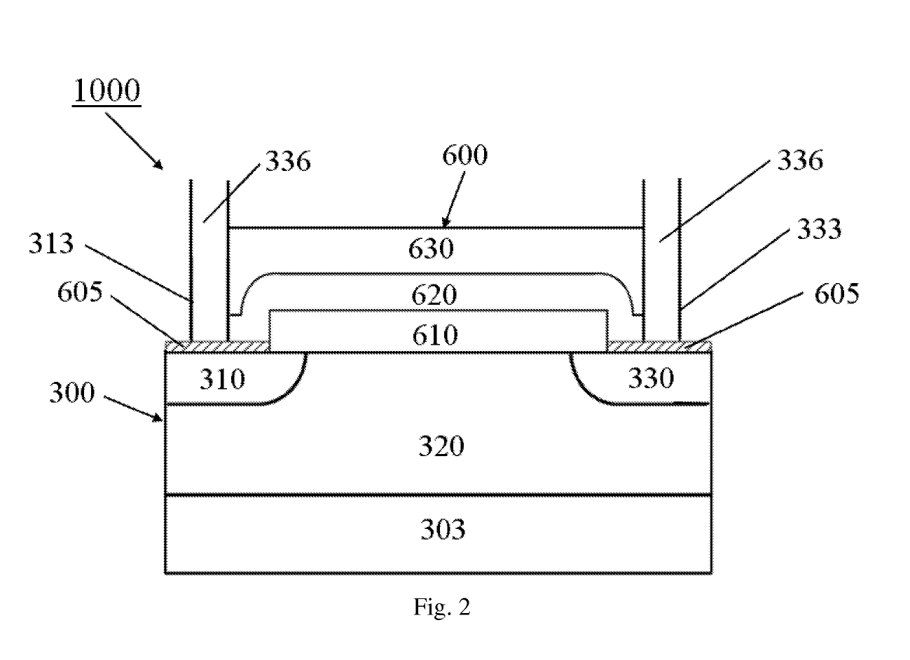

The present invention discloses a bipolar junction transistor having a carrier trapping layer, the structure us shown in FIG. 2. In one embodiment of the present invention, as shown in FIG. 1, a bipolar junction transistor 300 is provided, formed on the semi-conductor wafer or substrate. The bipolar junction transistor 300 comprises an emitter 310, a base 320, and a collector 330. In one embodiment, the bipolar junction transistor 300 mentioned above is formed on a semi-conductor substrate 303.

In one embodiment of the present invention, the material of the bipolar junction transistor 300 can be any semi-conductor material, such as comprising but not limiting to monocrystalline silicon, SiGe, GaAs wafer or substrate, and so on.

In one preferred embodiment of the present invention, the bipolar junction transistor 300 is a PNP type bipolar junction transistor, the manufacturing process will be described in general hereinafter: prepare a P-type silicon substrate wafer with the electrical resistivity about 8˜12 Ω-cm; the first photolithographic mask is used to define the active area on the wafer for forming the N well by photolithography process. The second photolithographic mask is then utilized to protect the area other than the N well. An ion implantation or ion diffusion is performed to implant the impurity when forming the N-type semiconductor, such as phosphorus, into the area on the wafer without shielding by a photoresist. After the removal of the photoresist, the impurity is activated by thermal annealing. The foregoing ion implant procedure of N well may comply one or several times, depend on the needs. The photoresist is formed to expose the emitter region 310 and the collector region 330 of the bipolar junction transistor, for the convenience of proceeding the P+ ion implantation; an ion implanter is introduced to dope P-type semiconductor, form the P-type emitter region 310 and collector region 330.

In another preferred embodiment of the present invention, bipolar junction transistor 300 is a NPN-type bipolar junction transistor, the manufacturing process is generally the same as the PNP-type bipolar junction transistor, the difference is that the type of ion is opposite.

In one embodiment of the present invention, as shown in FIG. 2, a carrier trapping layer is formed on the substrate 303 to form a bipolar junction transistor having a carrier trapping layer 1000. In other words, a carrier trapping structure 600 is formed on the bipolar junction transistor 300 shown in FIG. 1, wherein the non-volatile carrier trapping structure 600 comprises a first insulation layer 610 formed on the base region 320 of the bipolar junction transistor 300 and partially overlapped over the emitter region 310 and the collector region 330 respectively; a carrier trapping layer 620 formed above the first insulation layer 610. Afterwards, a selective etching is performed on the carrier trapping layer covered on the emitter region 310 and collector region 330 respectively, an emitter region plug hole 313 and a collector region plug hole 333 are formed respectively. The method of etching the plug holes 313 and 333 described above includes, but not limit to, dry etching or wet etching. The plug 336 can be formed in the emitter region plug hole 313 and the collector region plug hole 333 respectively. The plug 336 can be formed by high temperature aluminum or tungsten-plug etching back or selective tungsten etching technology. In other embodiment, plug 336 can be formed by metal alloy, silicon, silicide metal or other suitable metal.

In the other embodiment of the present invention, as shown in FIG. 2, silicide 605 layer can be formed on the area not covered by the first insulation layer 610 on bipolar junction transistor 300, material of silicide 605 may includes, but not limit to, TiSi2, NiSi, CoSi2, WSi2, and so on, the silicide may lower the contact resistant between the silicide and the silicon 1 (about 10-8 Ω/cm2) and provide a conductive material for improving the conduction to reach ohmic contact when the plug contacts with emitter region 310/collector region 330. The foregone silicide 605 layer can be formed by the process of self-aligned silicide (salicide). A second insulation layer 630 is able to be formed on the carrier trapping layer 620 for protecting or separating the bipolar junction transistor having a carrier trapping layer 1000.

In one embodiment of the present invention, the bipolar junction transistor is provided having a carrier trapping layer 1000, wherein the material of the first insulation layer 610 can be silica or other appropriate dielectric layer. The manufacturing process of the first insulation layer 610 can be any method of deposition, such as thermal oxidation or thin film vapor deposition, but it is preferably formed by wet ambient oxidation, when the quality of the oxide is not essential, but the growth rate is concern, the oxidation rate of the wet ambient oxidation is higher for saving time of manufacture; the manufacturing process of wet ambient oxidation will be substantially described hereinafter: the silicon wafer is exposed to oxygen environment, oxidation reaction Si₍ₛ₎+2H₂O_{(g)}→SiO₂₍ₛ₎+2H_{2(g)} occurs to silicon atoms on surface of the wafer, to form silica layer on the surface of the silicon wafer. The possible deposited thickness of the first insulation layer 610 is 10 nm to 30 nm, preferably, is 15 nm to 20 nm.

In one embodiment of the present invention, a bipolar junction transistor is provided with a carrier trapping layer 1000, wherein the material of the carrier trapping layer 620 can be any dielectric layer material which has the capability of trapping carrier such as electronic hole or electron, the dielectric layer may be with high dielectric constant, oxide with high dielectric constant, more particularly, such as oxynitride or silicon nitride. The carrier trapping layer 620 is formed on the first insulation layer 610 by thin film oxidation method. The deposited thickness of the the carrier trapping layer 620 is around 20 nm to 60 nm, preferably, is 30 nm to 40 nm.

In one embodiment of the present invention, the channel length formed by the carrier trapping layer 620 (the width of the base region, the distance between the emitter region and collector region) is substantially 0.24 μm to 0.32 μm in the 90 nm logic circuits process. If the width of the base region is under this range, the emitter region and the collector region will be short-circuit; if the width of the base region is wider than this range, the bipolar junction transistor will be failure, or will not function as bipolar junction transistor. Moreover, the channel length of created by carrier trapping layer 620 may substantially equals to minimum value of design specification, such as about 0.15 μm in the 90 nm logic circuits manufacture.

In one embodiment of the present invention, the thin film deposition is divided into physical vapor deposition (PVD) and chemical vapor deposition (CVD) depending on the chemical reaction is involved or not in the depositing process. Physical vapor deposition may comprise evaporation, molecular beam epitaxy (MBE) and sputter. Chemical vapor deposition comprises atmospheric pressure chemical vapor deposition (APCVD), low pressure chemical vapor deposition (LPCVD), and plasma enhanced chemical vapor deposition (PECVD). The thin film deposition in the present invention may use, but not limit to, these deposition methods described above, the preferred method is chemical vapor deposition.

In the preferred embodiment of the present invention, the first insulation layer 610 also can be referred to resist-protection oxide (RPO); the carrier trapping layer 620 may also perform the function of contact etch-stop layer (CESL); the second insulation layer 630 also can be referred to inter layer dielectric (ILD).

In one embodiment of the present invention, the bipolar junction transistor is provided to have a carrier trapping layer 1000, which injects electrons or electronic holes into silicon nitride (carrier trapping layer 620) of non-volatile carrier trapping structure 600 by impact ionization, the trapped electrons or electronic holes are induced to form a channel in base region 320 of bipolar junction transistor 300, thereby allowing the collector current increases when the transistor is in general operation, and higher current gain is achieved. Injected electrons or electronic holes into carrier trapping layer 620 by using impact ionization may change the current gain feature of bipolar junction transistor 300 to obtain the effect of modulating current gain. The effect of modulating current gain feature described above can be achieved, and can be practically applied to the operate amplifiers for replacing the variable resistor in the prior art. When operating an amplifier, differential input stage uses constant current load, differential transistor is replaced by a pair of bipolar junction transistor having a carrier trapping layer 1000. Furthermore, according to prior art proceeding circuit design, the present invention introduces a trimming circuit to inject electrons or holes into the carrier trapping layer, it is totally different from means of prior art. The present invention not only can increase current gain but also can enhance the utilization of wafer area. After the practical circuit is finished, the fine tune can be proceeding. The high voltage pulse input to the bipolar junction transistor having carrier trapping layer 1000 by using trimming circuit may gradually increase the current gain of transistor on each side till the matching between both sides are met to complete the self-tuning procedure.

Moreover, in one embodiment of the present invention provides bipolar junction transistor having a carrier trapping layer 1000. The first insulation layer 610 is formed on top of the base region 320 of the bipolar junction transistor 300, and partially overlapped on the emitter region 310 and the collector region 330 respectively, to separate the emitter-base region from the carrier trapping layer 620 and the base-collector region from the carrier trapping layer 620, therefore, the base region will not be exposed even if the lithography of the resist-protection oxide is misalignment when the channel of is formed by the carrier trapping layer 620, preventing the isolation between carrier trapping layer 620 and base-collector region from being failure.

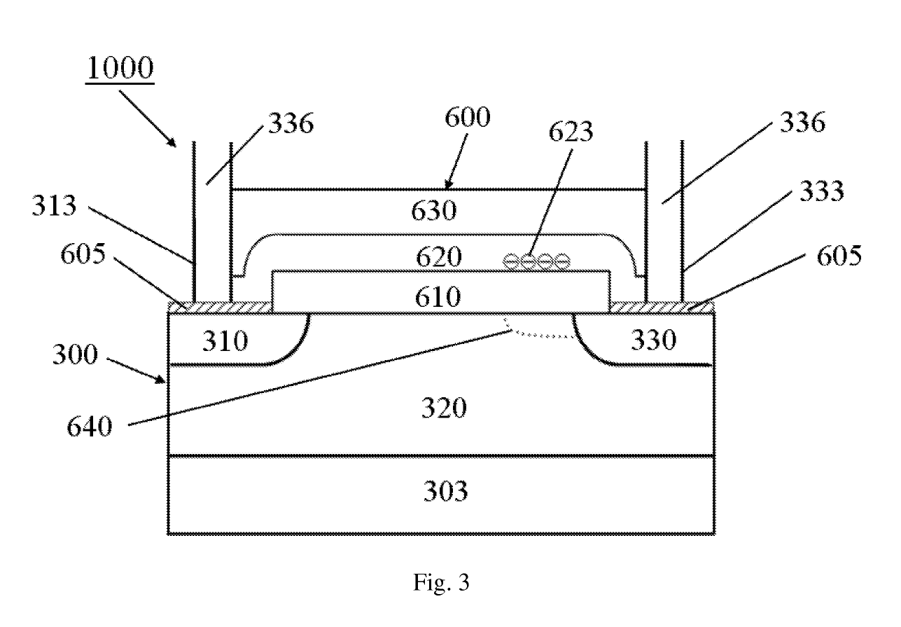

In one embodiment of the present invention, as shown in FIG. 3, it illustrates the operation mode of PNP-type of bipolar junction transistor having carrier trapping layer 1000 of present invention. When programming, negative high voltage is applied to the collector region 330, the emitter region 310 and the base region 320 are grounded. Numerous electron and hole pairs are generated by the impact Ionization which occurs in the collector region 330 and the electrons 623 are injected into the carrier trapping layer 620 randomly. The trapped electrons 623 in the carrier trapping layer 620 would induce inversion layer 640 from n well right below, causes the collector equivalent region extending toward to the emitter region 310, thereby moving the impact ionization zone inwardly. The iteration of the reaction will cause the collector equivalent region becomes longer and longer. To phrase another words, the shorter base region equivalent length will improve the totally gain of the bipolar junction transistor having a carrier trapping layer 1000.

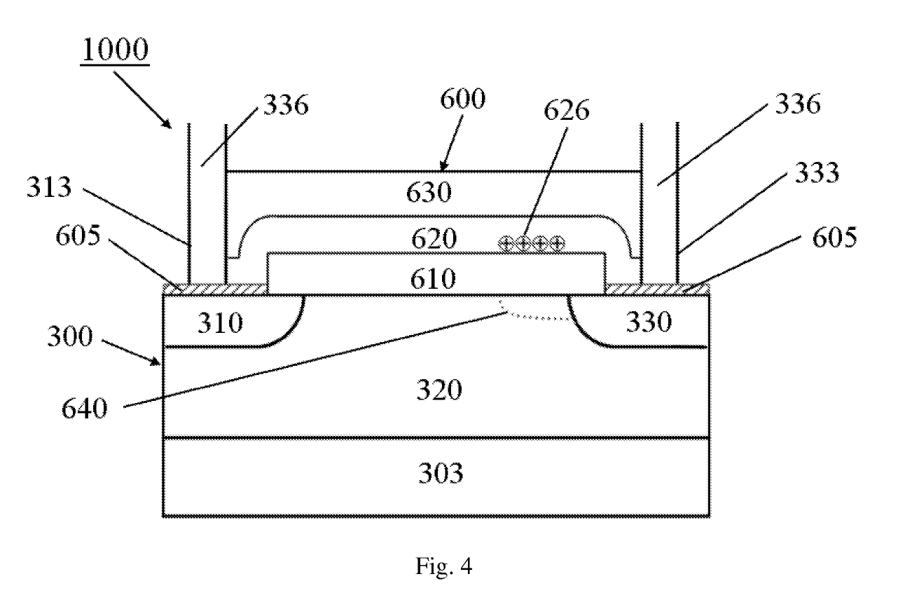

In one embodiment of the present invention, as shown in FIG. 4, it shows the operation mode of NPN-type of bipolar junction transistor having carrier trapping layer 1000 of present invention. When programming, a positive high voltage is applied to the collector region 330, emitter region 310 and base region 320 are grounded. Numerous electron and hole pairs are generated by the impact Ionization which occurs in the collector region 330, and the holes 626 are injected into the carrier trapping layer 620 randomly. The trapped hole 626 in the carrier trapping layer 620 would induce inversion layer 640 from p well right below, cause the collector region equivalent region extending toward to the emitter region 310, thereby moving the impact ionization zone inwardly. The reiteration of the reaction will cause the collector equivalent region becomes longer and longer. To phrase another words, the shorter base region equivalent length will improve the totally gain of the bipolar junction transistor having a carrier trapping layer 1000. In one embodiment of the present invention, as shown in FIG. 3 and FIG. 4, when the bipolar junction transistor having carrier trapping layer 1000 of present invention can be regarded as two bipolar junction transistors when reading. One is a bipolar junction transistor which is located within the well, and another one is the bipolar junction transistor formed on the surface of the substrate. The gain of the bipolar junction transistor on surface will increase due to the base region equivalent region width is narrower along with the operating time, and the under well bipolar junction transistor will not be influenced.

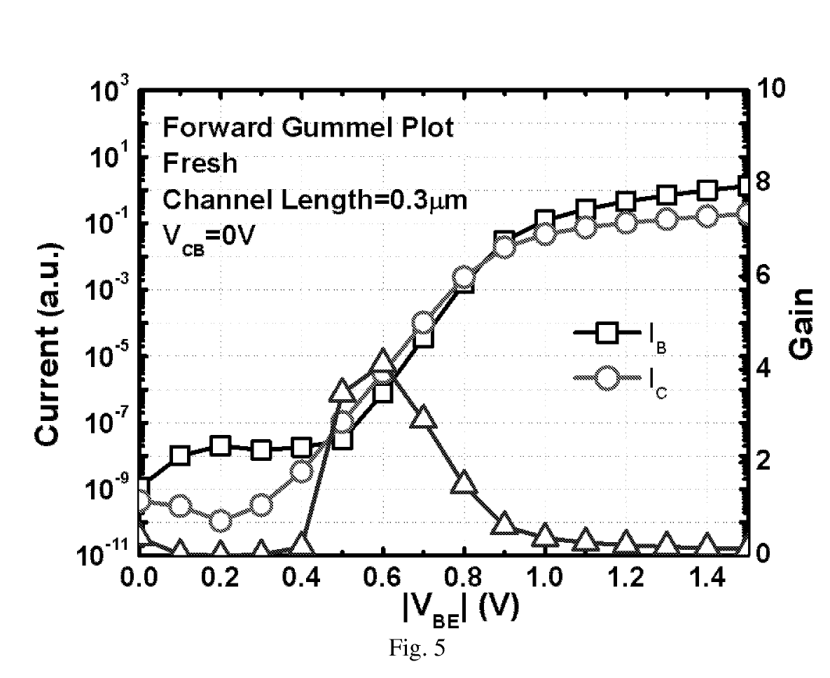

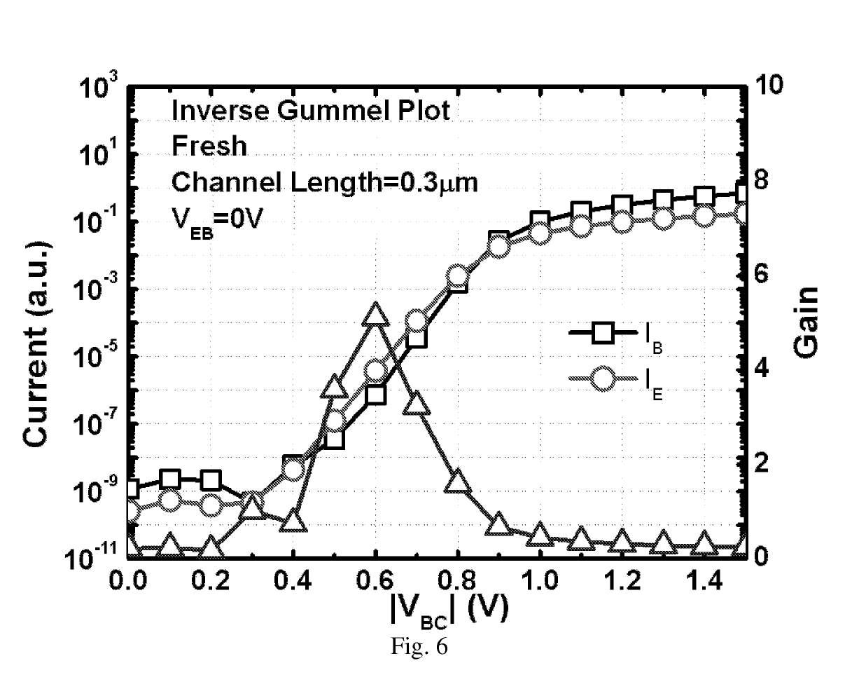

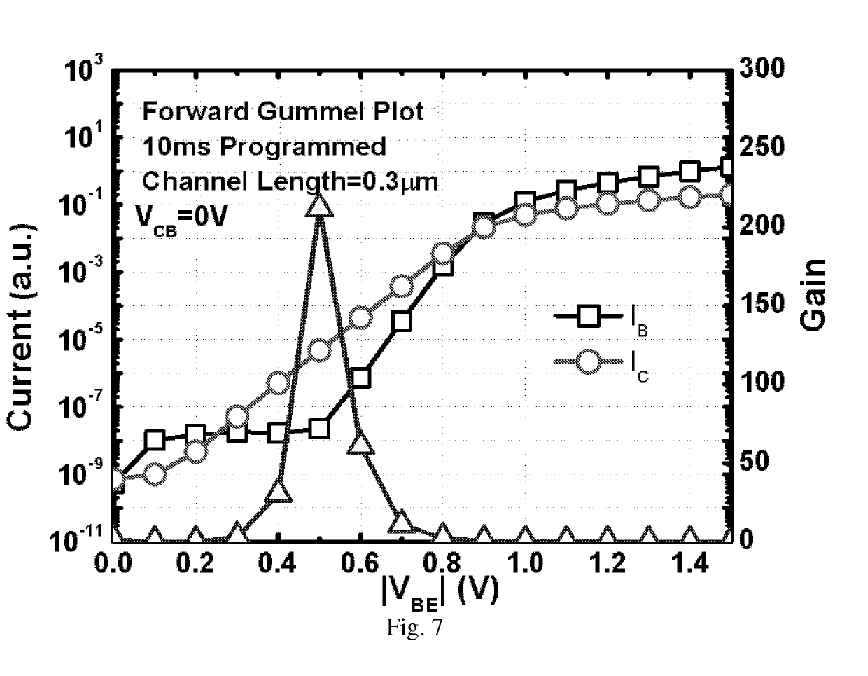

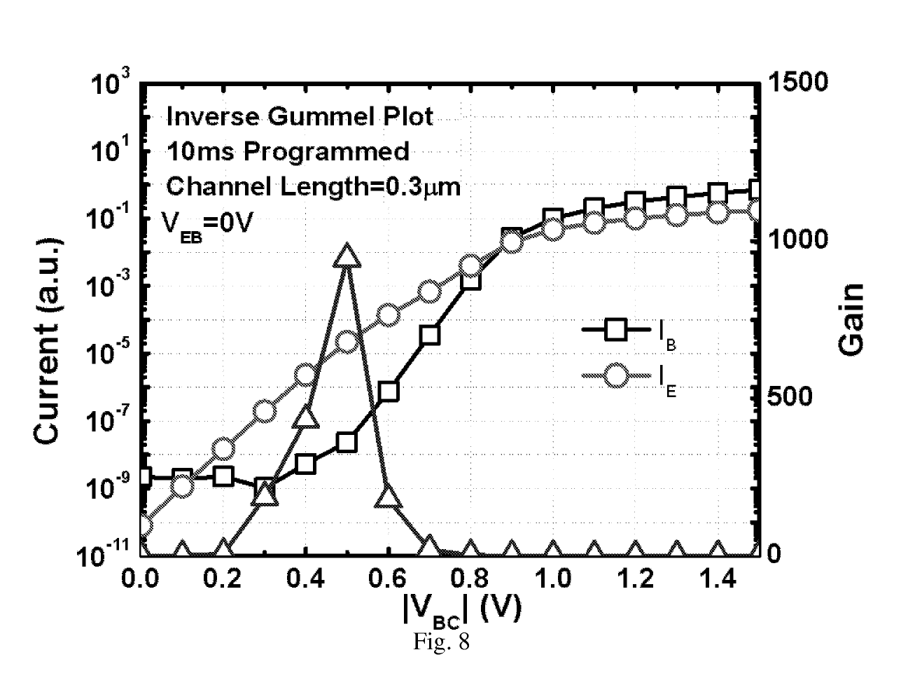

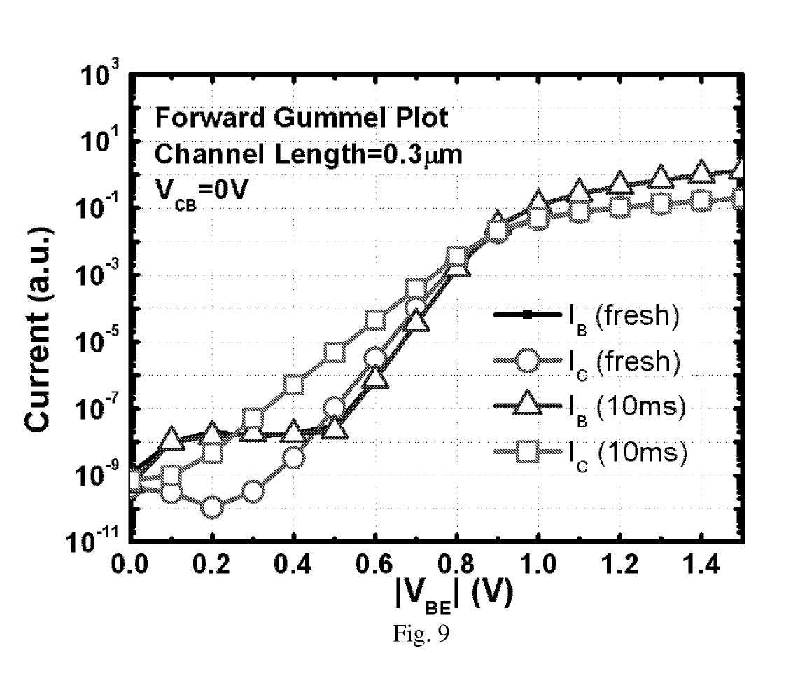

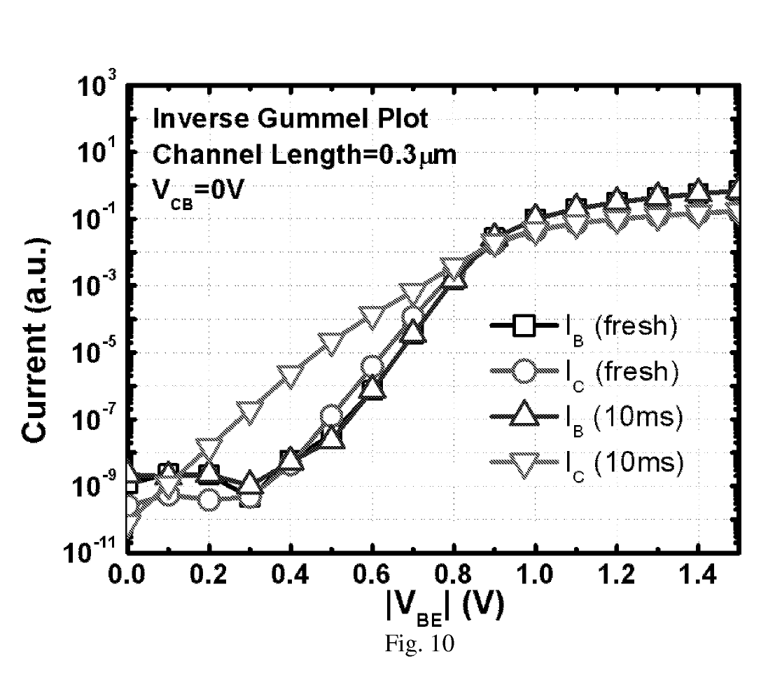

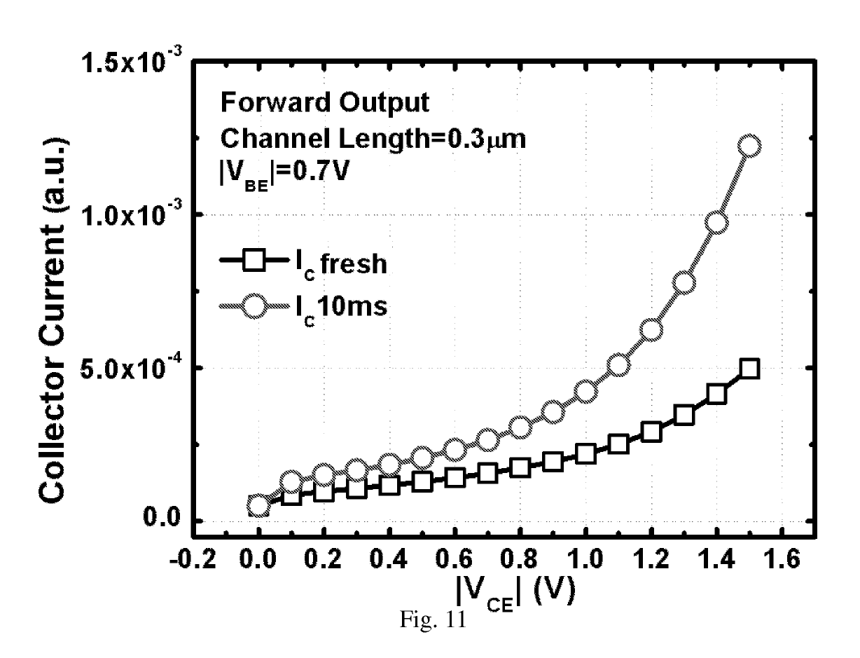

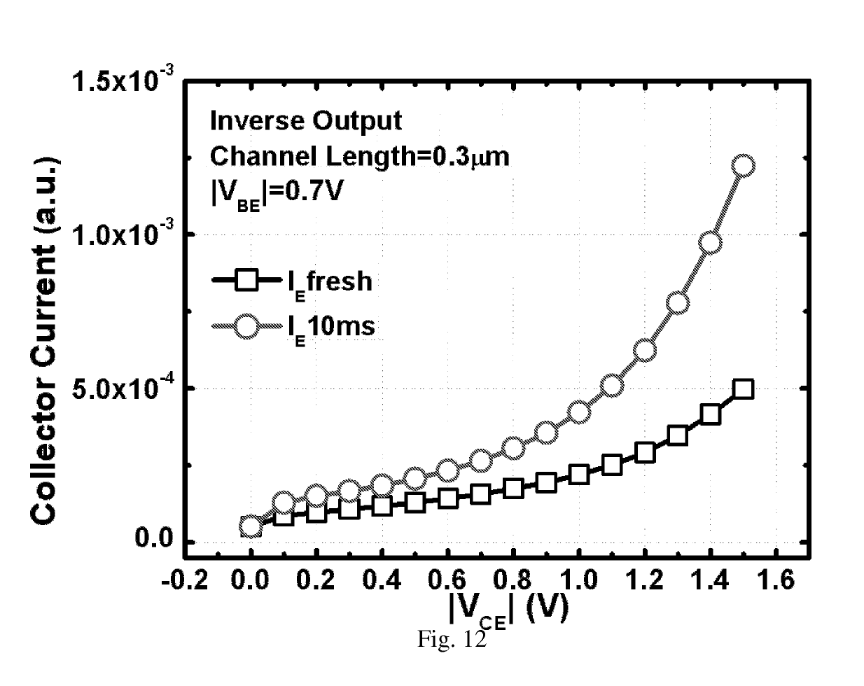

The actual effect of the bipolar junction transistor having carrier trapping layer 1000 of present invention may be referred to FIG. 5 to FIG. 12, FIG. 5 to FIG. 10 which shows Gummel plot of the bipolar junction transistor having carrier trapping layer of present invention. The following “forward” represents normal bipolar junction transistor operation, “inverse” represents operations of changing the role of emitter region 310 with collector region 330 with each other. The data acquiring conditions of FIG. 5 to FIG. 10 are: emitter region voltage 0 volt, base region voltage 0 to 1.5 volts, collector region voltage 0 to 1.5 volts. The data acquiring conditions of FIG. 11 and FIG. 12 are: emitter region voltage 0 volt, base region voltage −0.7 volts, collector region voltage 0 to −1.5 volts. FIG. 5 is a Gummel plot acquired when bipolar junction transistor proceeding forward operation, wherein FIG. 5 is a forward Gummel plot, the data acquiring condition is fresh, channel length 0.3 μm, collector region to base region voltage 0 volt; FIG. 6 is a Gummel plot acquired when bipolar junction transistor proceeding inverse operation, wherein FIG. 6 is an inverse Gummel plot, the data acquiring condition is fresh, channel length 0.3 μm, emitter region to base region voltage 0 volt; FIG. 7 is a Gummel plot acquired after bipolar junction transistor proceeding 10 ms of forward operation, wherein FIG. 7 is a forward Gummel plot, the data acquiring condition is after 10 ms operation, channel length 0.3 μm, collector region to base region voltage 0 volt; FIG. 8 is a Gummel plot acquired after bipolar junction transistor proceeding 10 ms of inverse operation, wherein FIG. 8 is an inverse Gummel plot, the data acquiring condition is after 10 ms operation, channel length 0.3 μm, emitter region to base region voltage 0 volt; FIG. 9 is a Gummel plot acquired at the instant and after 10 ms when bipolar junction transistor proceeding forward operation, wherein FIG. 9 is a forward Gummel plot, the data acquiring condition is channel length 0.3 μm, collector region to base region voltage 0 volt; FIG. 10 is a Gummel plot acquired at the instant and after 10 ms when bipolar junction transistor proceeding inverse operation, wherein FIG. 10 is an inverse Gummel plot, the data acquiring condition is channel length 0.3 μm, emitter region to base region voltage 0 volt; FIG. 11 is an output feature plot of the instant and after 10 ms of proceeding forward operation to bipolar junction transistor, wherein the data acquiring condition of FIG. 11 is channel length 0.3 μm, base region to emitter region voltage 0.7 volts; FIG. 12 is an output feature plot of the instant and after 10 ms of proceeding inverse operation to bipolar junction transistor, wherein the data acquiring condition of FIG. 11 is channel length 0.3 μm, base region to collector region voltage 0.7 volts. Among above, when base region to emitter region voltage is under 0.8 volts, bipolar junction transistor is at low current condition, increase of collector region current in bipolar junction transistor surface is reported on direct current feature plot; when base region to emitter region voltage is more than 0.8 volts, bipolar junction transistor in the well leads current, collector region current is covered by current in the well, therefore the affect is not obvious. According to foregoing data, it shows that the present invention can massively improve current gain and enhance the utilization of substrate area.

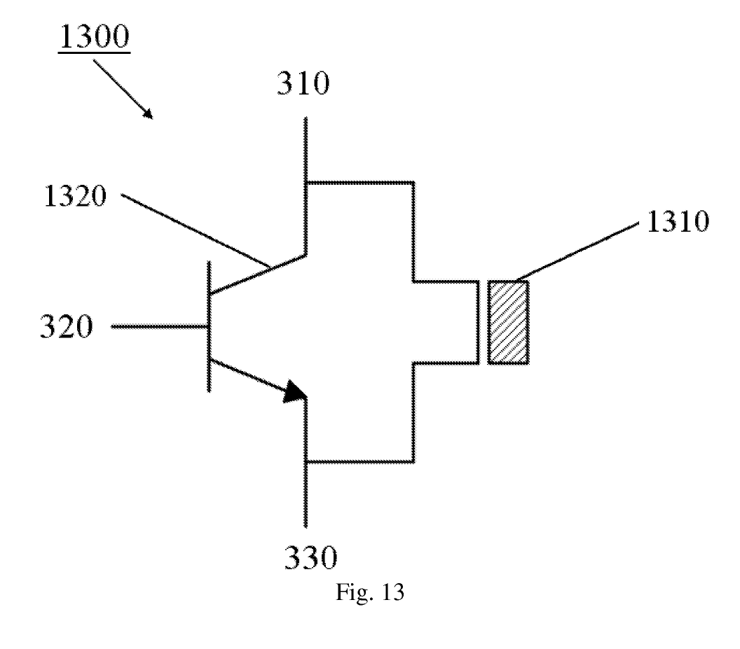

As described above, the present invention discloses a novel electronic device, the bipolar junction transistor having carrier trapping layer 1300. Please refer to FIG. 13, the equivalent circuit of bipolar junction transistor having carrier trapping layer 1300, it looks like a parallel connecting structure of a non-volatile memory 1310 and a bipolar junction transistor 1320. The present invention discloses a bipolar junction transistor having carrier trapping layer 1300 comprises: a bipolar junction transistor; a non-volatile structure connected to the bipolar junction transistor in parallel; the non-volatile structure comprises a carrier trapping layer.

For providing thoroughly understanding of the present invention, there are some terminologies used in the foregoing description. However, it should be appreciated that certain specific details are not necessary in implementing the present invention. Therefore, each of the specific embodiments of the present invention is for purpose of description but not for purpose of limiting the present invention to a specific detail. For example, the layout of the functional block diagram may be modified under the teaching of the present invention, and the illustrated or not illustrated components may be replaced by components with similar functionalities or equivalents. Some components are not necessarily required when implementing the present invention. It should be obvious that some modifications or variations may be made under the teaching or suggestion of the embodiments of the present invention for better accommodation with different environments or conditions, but they should be included in the present invention. Therefore, the scope of the present invention should be defined by the following claims and the equivalents.

What is claimed is:

1. A bipolar junction transistor having a carrier trapping layer comprising:
a semi-conductor substrate including a well with a first type ions formed thereon;
two impurity regions with a second type ions formed opposite with each other over the well;
an insulation layer over the well, and edges extend over the second two impurity regions; and
a carrier trapping layer formed over the insulation layer.

2. The bipolar junction transistor having a carrier trapping layer as claim 1, wherein the first well is N well, the two impurity regions doped with P type impurity to form a PNP type bipolar junction transistor.

3. The bipolar junction transistor having a carrier trapping layer as claim 1, wherein the first well is P well, the two impurity regions doped with N type impurity to form a NPN type bipolar junction transistor.

4. The bipolar junction transistor having a carrier trapping layer as claim 1, wherein the distance between the two impurity regions is 0.24 μm to 0.32 μm.

5. The bipolar junction transistor having a carrier trapping layer as claim 1, wherein the material of the insulation layer is silica.

6. The bipolar junction transistor having a carrier trapping layer as claim 1, wherein the thickness of the insulation layer is 10 nm to 30 nm; preferred thickness of the insulation layer is between 15 nm to 20 nm.

7. The bipolar junction transistor having a carrier trapping layer as claim 1, wherein the material of the carrier trapping layer is dielectric layer with high dielectric constant; the material for the carrier trapping layer is oxynitride or silicon nitride.

8. The bipolar junction transistor having a carrier trapping layer as claim 1, wherein the thickness of the carrier trapping layer is 20 nm to 60 nm; preferred thickness of the carrier trapping layer is between 30 nm to 40 nm.

9. The bipolar junction transistor having a carrier trapping layer as claim 1, at least one plug hole is etched on upper side of the insulation layer and the carrier trapping layer over the two impurity regions respectively.

10. The bipolar junction transistor having a carrier trapping layer as claim 9, at least a plug is formed in the at least one plug hole for connecting to the two impurity regions.

11. The bipolar junction transistor having a carrier trapping layer as claim 1, wherein at least one second insulation layer is formed over the upper of the bipolar junction transistor having a carrier trapping layer for protecting the bipolar junction transistor having a carrier trapping layer.

12. The bipolar junction transistor having a carrier trapping layer as claim 11, wherein the material of the second insulation layer is silica.

13. The bipolar junction transistor having a carrier trapping layer as claim 2, further comprises metal silicides formed on two impurity regions.

14. The bipolar junction transistor having a carrier trapping layer as claim 3, further comprises metal silicides formed on two impurity regions.

15. A bipolar junction transistor having a carrier trapping layer comprising:
a bipolar junction transistor; and
a non-volatile memory connected to the bipolar junction transistor in parallel;
wherein the non-volatile memory includes a carrier trapping layer.

16. The bipolar junction transistor having a carrier trapping layer as claim 15, wherein the material of the carrier trapping layer is dielectric layer with high dielectric constant; the material for the carrier trapping layer is oxynitride or silicon nitride.

17. The bipolar junction transistor having a carrier trapping layer as claim 15, wherein the thickness of the carrier trapping layer is 20 nm to 60 nm; the preferred thickness of the carrier trapping layer is between 30 nm to 40 nm.
